(19) United States
(12) Patent Application Publication
(10) Pub. No.: US 2023/0299461 A1
(43) Pub. Date: Sep. 21, 2023

(54) ANTENNA-EQUIPPED SEMICONDUCTOR PACKAGE AND RESIN COMPOSITION FOR ANTENNA-EQUIPPED SEMICONDUCTOR PACKAGE

(71) Applicant: NAMICS CORPORATION, Niigata-shi (JP)

(72) Inventors: Hiroshi Takasugi, Niigata-shi (JP); Ryo Usami, Niigata-shi (JP); Fumikazu Komatsu, Niigata-shi (JP); Shin Teraki, Niigata-shi (JP)

(73) Assignee: NAMICS CORPORATION, Niigata-shi (JP)

(21) Appl. No.: 18/010,265

(22) PCT Filed: Jun. 17, 2021
(86) PCT No.: PCT/JP2021/023019

§ 371 Date: Dec. 14, 2022

(30) Foreign Application Priority Data
Jul. 3, 2020 (JP) 2020-115697

(51) Int. Cl. H01Q 1/22; H01B 3/44; H01L 23/66

(52) U.S. Cl. CPC H01Q 1/2283; H01B 3/442; H01L 23/66; H01L 2223/6677

(57) ABSTRACT

Provided is an antenna-equipped semiconductor package which is excellent in solder heat resistance and has low transmission loss. In the antenna-equipped semiconductor package 100 in which an antenna unit 5 is integrally formed in a semiconductor device unit 10, at least one of an insulating layer 1 for connecting the semiconductor device unit 10 and the antenna unit 5 and an insulating layer 1 inside the antenna unit is a cured product of a resin composition including (A) a styrene-based elastomer having a double bond and (B) a compound generating a radical.

### TECHNICAL FIELD

The present invention relates to an antenna-equipped semiconductor package and a resin composition for an antenna-equipped semiconductor package. More specifically, the present invention relates to an antenna-equipped semiconductor package and a resin composition for an antenna-equipped semiconductor package, which are excellent in solder heat resistance and have low transmission loss.

### BACKGROUND ART

The standardization of 5G as a next-generation communication technology is progressing, and the market demand for realizing high-frequency equipment is increasing. Technological developments such as multi-element antenna technology and high-speed transmission are accelerated, communication capacity is also increased by the use of high-frequency band, and the generation amount of high-frequency noise and heat is also increased at the same time as the improvement of information processing capability, and the countermeasure becomes a big problem.

A 5G millimeter-wave antenna is required to have a structure in which a conductor-loss is reduced (in other words, transmission loss is reduced) by shortening a wire length between the antenna and the IC in terms of packaging technology. For this reason, in recent years, an antenna-equipped semiconductor package (for example, an antenna-in-package (AiP) or an antenna-on-package (AoP)) in which an antenna unit is integrally formed with a semiconductor device portion has been developed (for example, refer to Non-Patent Documents 1 and 2).

### CITATION LIST

### Non-Patent Document

[Non-Patent Document 1] Kaoru Sudo, 2 others, “Antenna and Packaging Technology for 5G Millimeter Wave Communication”, [online], Murata Manufacturing Co., Ltd., [Search on Apr. 2, 2020], Internet <URL:https://apmc-mwe.org/mwe2019/pdf/WS_01/TH5B-2_1.pdf>
[Non-Patent Document 2] Mayuko Murao, “Fujikura is developing 28 GHz-band RF IC, integrated with antenna”, [online], EE Times Japan, [Search on Apr. 2, 2020], Internet <URL:https://eetimes.jp/ee/articles/1908/09/news033.html>

### SUMMARY OF THE INVENTION

### Problem to be Solved by the Invention

Manufacturing of an antenna-equipped semiconductor package includes a solder reflow process for soldering in a semiconductor device unit. For this reason, a solder heat resistance is required for an antenna-equipped semiconductor package. Of course, a solder heat resistance is also required for an insulating layer for connecting a semiconductor device unit and an antenna unit, and also for an insulating layer inside the antenna unit. The above-described insulating layer is also required to have high-frequency characteristic.

The present invention has been made in view of the problems of the prior art. The present invention provides an antenna-equipped semiconductor package having excellent solder heat resistance and low transmission loss, and a resin composition for an antenna-equipped semiconductor package used in such an antenna-equipped semiconductor package.

### Means for Solving the Problem

According to the present invention, there are provided an antenna-equipped semiconductor package and a resin composition for an antenna-equipped semiconductor package described below.

[1] An antenna-equipped semiconductor package in which an antenna unit is integrally formed in a semiconductor device unit, wherein at least one of an insulating layer for connecting the semiconductor device unit and the antenna unit, and an insulating layer inside the antenna unit, is a cured product of a resin composition containing (A) a styrene-based elastomer having a double bond and (B) a compound generating a radical.

[2] The antenna-equipped semiconductor package according to [1], wherein a total mass of an epoxy resin and a curing agent in the cured product is 5 parts by mass or less with respect to 100 parts by mass of a total of the styrene-based elastomer (A) having a double bond and the compound (B) generating a radical.

[3] The antenna-equipped semiconductor package according to [1] or [2], wherein the styrene-based elastomer (A) having a double bond comprises a styrene/butadiene/butylene/styrene block copolymer.

[4] The antenna-equipped semiconductor package according to any one of [1] to [3], wherein the cured product comprises PTFE fillers.

[5] A resin composition for an antenna-equipped semiconductor package, comprising: (A) a styrene-based elastomer having a double bond; and (B) a compound generating a radical.

[6] The resin composition for an antenna-equipped semiconductor package according to [5], wherein a total mass of an epoxy resin and a curing agent in the resin composition is 5 parts by mass or less with respect to 100 parts by mass of a total of the styrene-based elastomer (A) having a double bond and the compound (B) generating a radical.

[7] The resin composition for an antenna-equipped semiconductor package according to [5] or [6], wherein the styrene-based elastomer (A) having a double bond comprises a styrene/butadiene/butylene/styrene block copolymer.

[8] The resin composition for an antenna-equipped semiconductor package according to any one of [5] to [7], comprising PTFE fillers.

[9] A film for an antenna-equipped semiconductor package comprising the resin composition according to any one of [5] to [8].

### Effect of the Invention

The antenna-equipped semiconductor package of the present invention has advantages of excellent solder heat resistance and low transmission loss. Further, the resin composition for the antenna-equipped semiconductor package of the present invention has the advantage of being able to realize an antenna-equipped semiconductor package that is excellent in solder heat resistance and have low transmission loss.

### BRIEF DESCRIPTION OF THE DRAWINGS

FIG. 1 A schematic partial cross-sectional view showing the antenna-equipped semiconductor package of an embodiment according to the present invention.

FIG. 2 A schematic partial cross-sectional view showing the antenna-equipped semiconductor package of another embodiment of the present invention.

### MODE FOR CARRYING OUT THE INVENTION

Hereinafter, embodiments of the present invention will be described, but the present invention is not limited to the following embodiments. Therefore, it should be understood that the scope of the present invention includes modifications, improvements, and the like appropriately made to the following embodiments based on ordinary knowledge of a person skilled in the art without departing from the spirit of the present invention.

(1) Antenna-equipped semiconductor package:

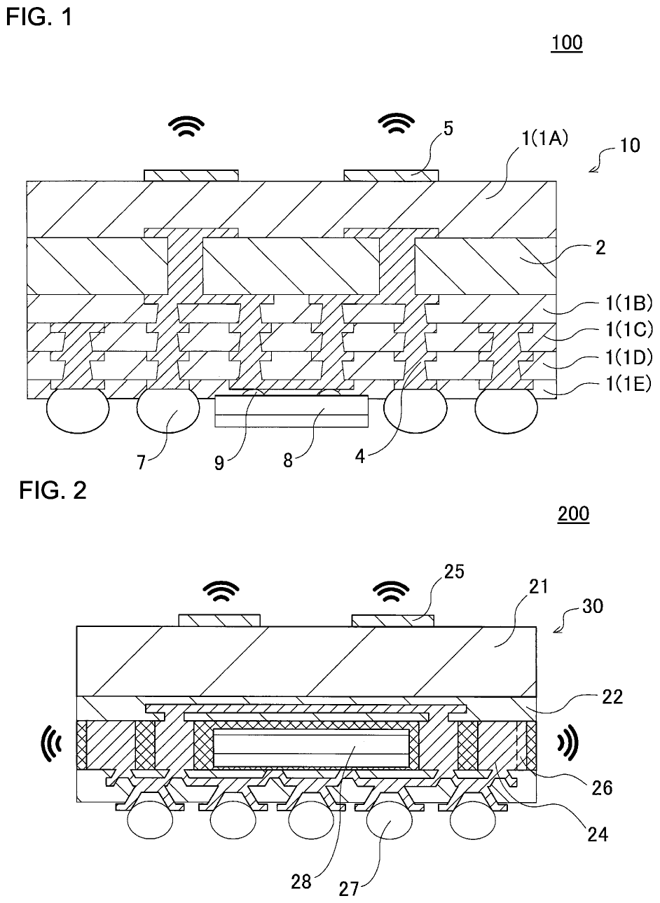

An embodiment of the antenna-equipped semiconductor package according to the present invention is an antenna-equipped semiconductor package 100 as shown in FIG. 1. FIG. 1 is a schematic partial cross-sectional view showing the antenna-equipped semiconductor package of an embodiment of the present invention.

As shown in FIG. 1, the antenna-equipped semiconductor package 100 of the present embodiment is an antenna-equipped semiconductor package 100 as a high-frequency substrate in which an antenna unit 5 is integrally formed in a semiconductor device unit 10, and in particular, an RF (radio frequency) chip 8 that performs 5G millimeter-wave transmission/reception communication is mounted. The antenna unit 5 is connected to the RF chip 8 that performs the millimeter-wave communication in the semiconductor device unit 10 by wiring layers 4 having various wiring patterns.

The semiconductor device unit 10 in the antenna-equipped semiconductor package 100 shown in FIG. 1 includes a core substrate 2, an antenna unit 5 arranged on one surface side of the semiconductor device unit 10, an insulating layer 1 (first insulating layer 1A) for connecting the semiconductor device unit 10 and the antenna unit 5, a multilayered wiring layer 4 disposed in the core substrate 2, and an insulating layer 1 (second insulating layer 1B, third insulating layer 1C, fourth insulating layer 1D, and fifth insulating layer 1E) configured to cover wiring vias in the wiring layer 4. The first insulating layer 1A may be provided not only so as to be interposed between the semiconductor device unit 10 and the antenna unit 5 but also so as to extend to the inside of the antenna unit 5.

In the antenna-equipped semiconductor package 100, a part of the wiring layer 4 is connected to the RF chip 8 that performs millimeter-wave transmission/reception communication on the other surface of the semiconductor device unit 10, and the other part of the wiring layer 4 is connected to an electrical connection metal 7. In the embodiment shown in FIG. 1, the wiring layer 4 and the RF chip 8 are electrically connected via hemispherical connecting pads 9. The electrical connection metal 7 is a terminal portion for physically and/or electrically connecting the antenna-equipped semiconductor package 100 to the outside through the electrical connection metal 7 according to the function thereof.

The current and the millimeter-wave signal outputted from the RF chip 8 are transmitted to the antenna unit 5 to efficiently radiate in space while suppressing the attenuation of them at the time of transmitting, so that the insulating layer 1 is required to reduce loss (transmission loss) of a connecting portion connecting the antenna unit 5 and the RF chip 8. Similarly, at the time of receiving, in order to transmit the reflected wave of the millimeter-wave signal received by the antenna unit 5 to the RF chip 8 as the reception unit while suppressing the attenuation of the reflected wave, it is required to reduce the loss (transmission loss) of the connecting portion connecting the antenna unit 5 and the RF chip 8.

The antenna unit 5 is arranged on one surface side of the semiconductor device unit 10 as a patch antenna of a planar antenna.

The antenna-equipped semiconductor package 100 of the present embodiment has particularly main features with respect to the configuration of the insulating layer 1 (for example, the first insulating layer 1A) for connecting the semiconductor device unit 10 and the antenna unit 5, or the insulating layer 1 inside the antenna unit 5. Hereinafter, the structure of the insulating layers 1 in the antenna-equipped semiconductor package 100 of the present embodiment will be further described in detail. Hereinafter, the insulating layer 1 for connecting the semiconductor device unit 10 and the antenna unit 5 and the insulating layer 1 inside the antenna unit 5 may be collectively referred to simply as an “insulating layer 1”.

In the antenna-equipped semiconductor package 100 of the present embodiment, the insulating layer 1 is a cured product of a resin composition containing (A) a styrene-based elastomer having a double bond and (B) a compound generating a radical. The antenna-equipped semiconductor package 100 including the insulating layer 1 configured as described above is excellent in solder heat resistance and can reduce transmission loss. In the antenna-equipped semiconductor package 100 provided with the antenna unit 5 for 5G millimeter wave, for example, a solder test at 288° C. is sometimes performed on the insulating layer 1 for connecting the antenna unit 5, and a solder heat resistance at a heat-resistant temperature which is conventionally not required is required. Although known high-frequency films are used as the insulating layers in the conventional semiconductor package, such high-frequency films do not satisfy the above-described solder heat resistance, and many of the high-frequency films are not usable for the antenna-equipped semiconductor package 100 provided with the antenna unit 5 for 5G millimeter wave. In the antenna-equipped semiconductor package 100 of the present embodiment, it is preferable that the cured product constituting the insulating layer 1 has a dielectric loss tangent (tan δ) of 0.0020 or less as measured by SPDR (split post dielectric resonator) method at a frequency of 10 GHz, and a solder heat resistance of 290° C. for 2 minutes or more.

The insulating layer 1 can be obtained by heat-curing a resin composition containing the styrene-based elastomer (A) having a double bond and the compound (B) generating a radical.

Examples of the styrene-based elastomer (A) having a double bond include a block copolymer containing a block of styrene or an analog thereof as at least one end block and containing an elastomer block of a conjugated diene as at least one intermediate block. Examples thereof include styrene/butadiene/styrene-based elastomers (SBSs) and styrene/butadiene/butylene/styrene-based elastomers (SBBS). The cured product of the resin-composition containing the styrene-based elastomer (A) having a double bond has excellent solder heat resistance. In particular, from the viewpoint of high-frequency characteristics, a styrene-based elastomer containing a styrene/butadiene/butylene/styrene block copolymer can be preferably exemplified as the styrene-based elastomer (A) having a double bond. The component (A) may be a reactive elastomer provided with functional groups such as amines. By using a reactive elastomer provided with functional groups, the adhesive strength (peel strength) can be further improved. The weight average molecular weight of the component (A) is preferably from 20,000 to 200,000, more preferably from 30,000 to 150,000. The weight average molecular weight is determined by gel permeation chromatography (GPC) using a calibration curve of standard polystyrene.

Specific examples of the styrene-based elastomer (A) having a double bond include trade names “TR2827”, “TR2000”, “TR2003”, and “TR2250” manufactured by JSR Corporation, and trade names “P1083”, “P1500”, “P5051”, and “MP10” manufactured by Asahi Kasei Chemicals Corporation.

Examples of the compound (B) generating a radical include a degradable compound and a non-degradable compound. Examples of the degradable compound include a radical generator such as an organic peroxide and an azo compound. As the organic peroxide, diacyl peroxides such as benzoyl peroxide, isobutyryl peroxide, isononanoyl peroxide, decanoyl peroxide, lauroyl peroxide, parachlorobenzoyl peroxide, and di(3,5,5-trimethylhexanoyl)peroxide; peroxyketals such as 2,2-di(4,4-di-(di-tert-butylperoxy)cyclohexyl)propane; peroxydicarbonates such as isopropyl perdicarbonate, di-sec-butyl perdicarbonate, di-2-ethylhexyl perdicarbonate, di-1-methylheptyl perdicarbonate, di-3-methoxybutyl perdicarbonate. and dicyclohexyl perdicarbonate; peroxyesters such as tert-butyl perbenzoate, tert-butyl peracetate, tert-butyl per-2-etylhexanoate, tert-butyl perisobutyrate, tert-butyl perpivalate, tert-butyl diperazipate, cumyl perneodecanoate, tert-butyl peroxybenzoate and 2,5-dimethyl-2,5-di(benzoyl peroxy)hexane; ketone peroxides such as methylethyl ketone peroxide and cyclohexanone peroxide; dialkyl peroxides such as di-tert-butyl peroxide, dicumyl peroxide, tert-butyl cumyl peroxide, 2,5-dimethyl-2,5-di(t-butylperoxy)hexane, 2,5-dimethyl-2,5-di(t-butylperoxy)hexyne-3, 1,1-di(t-hexylperoxy)-3,3,5-trimethylcyclohexane, di-tert-hexyl peroxide, di(2-tert-butylperoxyisopropyl)benzene; hydroperoxides such as cumene hydroxy peroxide, tert-butyl hydroperoxide and p-menthahydroperoxide can be used. Although there is no particular limitation on the organic peroxide to be used, in the case where the insulating layer 1 is formed from a resin composition or a film containing a solvent, a drying step of about 60 to 80° C. is often required, and therefore, it is preferable to use the organic peroxide having a 10-hour half-life temperature of 100 to 140° C. Further, the 10-hour half-life temperature is more preferably 110 to 130° C. Specific examples thereof include dicumyl peroxide. Examples of the azo compound include azo esters. Examples of the non-degradable compound include a compound having an ethylenic double bond. Examples of the compound having an ethylenic double bond include a modified polyphenylene ether (PPE) having a vinyl group or a styrene group at the terminal, a maleimide compound, and the like. The number average molecular weight (Mn) of the modified polyphenylene ether (PPE) having a vinyl group or a styrene group at the terminal is preferably in the range of 1000 to 5000 in terms of polystyrene by the GPC method, more preferably in the range of 1000 to 3000, and still more preferably in the range of 1000 to 2500. The maleimide compound is preferably a dimer acid-modified bismaleimide having a number average molecular weight of 1000 to 8000.

As specific examples of the compound (B) generating a radical, the degradable compound includes a trade name “PERCUMYL D” manufactured by NOF Corporation, and a trade name “V-601” manufactured by FUJIFILM Wako Pure Chemical Corporation. Examples of the non-degradable compound include terminal-modified PPEs manufactured by Mitsubishi Gas Chemical Company Inc., trade names “OPE-2St 1200” and “OPE-2St 2200”

In the cured product constituting the insulating layer 1, the contents of the styrene-based elastomer (A) having a double bond and the compound (B) generating a radical are not particularly limited. The styrene-based elastomer (A) having a double bond is preferably contained in the resin composition in an amount of 25.0 to 99.8% by mass, more preferably 30.0 to 85.0% by mass, and still more preferably 35.0 to 85.0% by mass, based on the solid content. In addition, the compound (B) generating a radical is preferably contained in the resin composition in an amount of 0.1 to 70.0% by mass based on the solid content. When (B) is a degradable compound, (B) is preferably contained in the resin composition in an amount of 0.10 to 5% by mass, more preferably 0.10 to 2% by mass, and particularly preferably 0.10 to 1% by mass based on the solid content. When (B) is a non-degradable compound, (B) is preferably contained in the resin composition in an amount of 4 to 70% by mass, more preferably 5 to 30% by mass, and particularly preferably 6 to 15% by mass based on the solid content. With such a configuration, the solder heat resistance of the antenna-equipped semiconductor package 100 can be further improved while the adhesive strength (peel strength) is maintained, and transmission loss can be effectively reduced.

The cured product constituting the insulating layer 1 may further contain other components. Examples of the other components include cured products of thermosetting resins such as epoxy resins and various curing agents, inorganic fillers such as silica fillers, organic fillers such as PTFE fillers, and various additives such as colorants and dispersing agent. The cured product constituting the insulating layers 1 preferably further includes PTFE fillers. By including PTFE fillers, the high-frequency characteristics of the antenna-equipped semiconductor package 100 can be further improved. From the viewpoint of maintaining the adhesive strength (peel strength), the amount of the inorganic filler or the organic filler is preferably 50% by mass or less in the cured product constituting the insulating layer 1

The cured product constituting the insulating layer 1 may contain a cured product of a thermosetting resin such as an epoxy resin in addition to the styrene-based elastomer (A) having a double bond. However, the total mass of the epoxy resin component and the curing agent component in the cured product is preferably less than 10 parts by mass, and more preferably 5 parts by mass or less, with respect to 100 parts by mass of the total of the styrene-based elastomer (A) having a double bond and the compound (B) generating a radical. When the content of the epoxy resin component and the curing agent component in the cured product increases, the solder heat resistance and the dielectric loss tangent of the antenna-equipped semiconductor package 100 may deteriorate. In some embodiments, the cured product constituting the insulating layer 1 does not include a cured product of an epoxy resin.

The antenna-equipped semiconductor package 100 including the insulating layer 1 made of the cured product as described above is excellent in solder heat resistance and has low transmission loss, and thus is suitably used as a semiconductor package on which an RF (radio frequency) chip 8 for performing transmission/reception communication of 5G millimeter waves is mounted.

In the antenna-equipped semiconductor package 100 of the present embodiment, it is preferable that each of the first insulating layer 1A for connecting the semiconductor device portion 10 and the antenna unit 5, and the second insulating layer 1B, the third insulating layer 1C, the fourth insulating layer 1D, and the fifth insulating layer 1E, which are configured to cover the wiring vias in the wiring layer 4, is configured in the same manner as the insulating layer 1 made of the cured product described above.

Next, the method of manufacturing the insulating layer 1 in the antenna-equipped semiconductor package 100 of the present embodiment is not particularly limited, and examples thereof include the following methods.

First, a resin composition for an antenna-equipped semiconductor package containing (A) a styrene-based elastomer having a double bond and (B) a compound generating a radical is prepared. Hereinafter, the “resin composition for an, antenna-equipped semiconductor package” may be simply referred to as a “resin composition”. From the viewpoint of handling, the resin composition is preferably in the form of a film. The film for an antenna-equipped semiconductor package can be obtained, for example, by applying a solution obtained by adding an organic solvent to a resin composition containing (A) and (B) to a PET film subjected to a mold release treatment as a support, and drying the PET film at 80 to 130° C. The obtained film for an antenna-equipped semiconductor package is peeled from the support and attached to the semiconductor device unit 10, and heat treatment is performed at, for example, 200° C. for 30 to 60 minutes, whereby an antenna-equipped semiconductor package can be manufactured.

The configuration of the wiring layer 4 and the like in the semiconductor device unit 10 of the antenna-equipped semiconductor package 100 is not limited to the configuration shown in FIG. 1, and can be applied to various semiconductor packages including 5G millimeter-wave antennas. For example, FIG. 2 is a schematic partial cross-sectional view illustrating an antenna-equipped semiconductor package of another embodiment of the present invention.

In the antenna-equipped semiconductor package 200 shown in FIG. 2, the antenna units 25 and 26 are integrally formed in the semiconductor device unit 30. The antenna units 25 and 26 are connected to an RF chip 28 that performs millimeter-wave communication in the semiconductor device unit 10 by wiring layers 24 having various wiring patterns.

The semiconductor device unit 30 includes a core substrate 22, an antenna unit 25 disposed on one surface side of the semiconductor device unit 30, and an insulating layer 21 for connecting the semiconductor device unit 30 and the antenna unit 25. In the core substrate 22, an RF chip 28 that performs 5G millimeter-wave transmission/reception communication is accommodated, and is wired by the wiring layers 24 arranged in the core substrate 22. An antenna unit 26 as a dipole antenna in which straight conductive wires (elements) are arranged symmetrically is made at both ends of the semiconductor device unit 30. The other surface side of the semiconductor device unit 30 is connected to an electrical connection metal 27 for physically and/or electrically connecting the antenna-equipped semiconductor package 200 to the outside.

Also in the antenna-equipped semiconductor package 200 as shown in FIG. 2, the insulating layer 21 is made of a cured product of a resin composition containing (A) a styrene-based elastomer having a double bond and (B) a compound generating a radical, whereby solder heat resistance is excellent and transmission loss can be reduced. The cured product used as the insulating layer 21 can be adopted in the same manner as the cured product used as the insulating layer 1 of the antenna-equipped semiconductor package 100 shown in FIG. 1.

(2) Resin composition for antenna-equipped semiconductor package:

Next, an embodiment of the resin composition for the antenna-equipped semiconductor package of the present invention will be described. The resin composition for the antenna-equipped semiconductor package of the present embodiment is a resin composition for forming the insulating layer 1 of the antenna-equipped semiconductor package 100 as shown in FIG. 1.

The resin composition for the antenna-equipped semiconductor package of the present embodiment includes (A) a styrene-based elastomer having a double bond, and (B) a compound generating a radical. By heating and curing the resin composition for the antenna-equipped semiconductor package according to the present embodiment, an insulating layer for connecting the semiconductor device unit and the antenna unit of the antenna-equipped semiconductor package or an insulating layer inside the antenna unit can be formed. An insulating layer made of such a cured product of the resin composition has excellent solder heat resistance and low transmission loss.

Examples of the styrene-based elastomer (A) having a double bond include styrene/butadiene/styrene-based elastomer (SBS), styrene/butadiene/butylene/styrene-based elastomer (SBBS), and the like. In particular, from the viewpoint of high-frequency characteristics, a styrene-based elastomer containing a styrene/butadiene/butylene/styrene block copolymer can be preferably exemplified. The content of the styrene-based elastomer (A) having a double bond is not particularly limited, and preferred amounts are as described above.

Examples of the compound (B) generating a radical include a degradable compound and a non-degradable compound as described above. Examples of the degradable compound include a radical generator such as an organic peroxide and an azo compound, and examples of the non-degradable compound include a compound having an ethylenic double bond. The content of the compound (B) generating a radical is not particularly limited, and preferred amounts are as described above.

The resin composition for the antenna-equipped semiconductor package of the present embodiment may further include other components. Examples of the other components include thermosetting resins such as epoxy resins and various curing agents, inorganic fillers such as silica fillers, organic fillers such as PTFE fillers, and various additives such as colorants and dispersing agents. The resin composition for the antenna-equipped semiconductor package of the present embodiment preferably includes further a PTFE filler. By including PTFE fillers, the high-frequency characteristics of the antenna-equipped semiconductor package 100 can be further improved. From the viewpoint of maintaining the adhesive strength (peel strength), the amount of the inorganic filler or the organic filler is preferably 50% by mass or less of the resin composition for the antenna-equipped semiconductor package.

The total mass of the epoxy resin and the curing agent in the resin composition for the antenna-equipped semiconductor package is preferably less than 10 parts by mass, and more preferably 5 parts by mass or less with respect to 100 parts by mass of the total of (A) a styrene-based elastomer having a double bond and (B) a compound generating a radical. When the content of the epoxy resin and the curing agent increases, the solder heat resistance and the dielectric loss tangent of the insulating layer formed of the cured product of the resin composition for the antenna-equipped semiconductor package may deteriorate. In some embodiments, the resin composition for the antenna-equipped semiconductor package does not include an epoxy resin.

### EXAMPLE

Hereinafter, the present invention will be described in more detail by examples, but the present invention is not limited by these examples in any way. In the following examples, “parts” represents parts by weight, and “percentages” represents percentages by weight, unless otherwise specified.

### Example 1

In Example 1, a resin composition for an antenna-equipped semiconductor package was prepared as follows. First, 99.75 parts of a styrene-based elastomer having a double bond (partially hydrogenated) was prepared as the styrene-based elastomer (A3) of the component (A), and 0.25 parts of a compound generating a degradable radical was prepared as the compound (B1) generating a radical of the component (B). As the styrene-based elastomer (A3), trade name “P1500” manufactured by Asahi Kasei Chemicals Corporation was used. As the compound (B1) for generating a radical, an organic peroxide of trade name “PERCUMYL D” manufactured by NOF Corporation was used.

After the component (A) and the component (B) were measured and blended, they were mixed and dissolved together with an organic solvent while rotating at a rotational speed of 150 rpm to prepare a coating solution for the resin composition for the antenna-equipped semiconductor package of Example 1.

Next, the coating solution was applied to one side of a support and dried at 120° C. to obtain an adhesive film with a support. As the support, a PET film subjected to a mold release treatment was used.

The PET film subjected to a mold release treatment was disposed on the obtained adhesive film with a support to obtain a film laminated body of PET film/adhesive film/PET film. The film laminated body was subjected to hot pressing under hot-pressing conditions of a pressing temperature of 200° C., a temperature holding time of 60 minutes, and a pressing pressure of 0.98 MPa to thermally cure the adhesive film.

After removing the above-described PET film disposed on both surfaces of the cured adhesive film, a test specimen A made of the resin composition for the antenna-equipped semiconductor package of Example 1 was prepared. The test specimen A of Example 1 thus obtained was evaluated for the following dielectric constant (ε) and dielectric loss tangent (tan δ). The results are given in Table 1.

(Dielectric constant (ε) and Dielectric loss tangent (tan δ))

A rectangular test piece having one side of 50±0.5 mm and the other side of 70±2 mm was cut out from the cured adhesive film of the test specimen A, and the thickness of the cut-out test piece was measured. The dielectric constant (ε) and the dielectric loss tangent (tan δ) of the test piece whose thickness was measured were measured at a frequency of 10 GHz by SPDR (Split Post Dielectric Resonator) method. The dielectric loss tangent (tan δ) was evaluated by the following evaluation criteria.
Evaluation “Excellent”: Dielectric loss tangent (tan δ) is 0.0015 or less.
Evaluation “Good”: Dielectric loss tangent (tan δ) is more than 0.0015 and 0.0020 or less.
Evaluation “Not possible”: Dielectric loss tangent (tan δ) is over 0.0020.

(Peel Strength)

Copper foils having one surface roughened were prepared. The copper foils were bonded with the roughened surfaces facing inward to obtain a laminated body of copper foil/adhesive film/copper foil. The laminated body was thermally pressure-bonded and cured using a vacuum press machine at 200° C. for 60 minutes under 0.98 MPa. The cured body was cut to a width of 10 mm to prepare a sample for peel strength measurement (a test specimen B). The test specimen B was peeled off by Autograph (model number: ASG-J-5kNJ) manufactured by Shimadzu Corporation, and the peel strength was measured. The peel strength was measured in accordance with JIS C 6471. For the measurement results, an average value of each N=5 was calculated. The peel strength was evaluated according to the following evaluation criteria.

Evaluation “Excellent”: Peel strength is 5N/cm or more. Evaluation “Good”: Peel strength is 2N/cm or more and less than 5N/cm. Evaluation “Not possible”: Peel strength is less than 2N/cm.

(Solder Heat Resistance Test)

Copper foils having one surface roughened were prepared. The copper foils were bonded with the roughened surface facing inward to obtain a laminated body of copper foil/adhesive film/copper foil. The laminated body was thermally pressure-bonded and cured using a vacuum press machine at 200° C. for 60 minutes under 0.98 MPa. The test piece was cut into squares so that each side was 30 mm, to prepare a sample for solder heat resistance test (a test specimen C). Thereafter, the specimen C was floated to a solder bath at 290° C., and the presence or absence of swelling was confirmed. The solder heat resistance test was performed in accordance with JIS C 5012 1993. The solder heat resistance test was evaluated according to the following evaluation criteria.
Evaluation “Excellent”: The time until swelling is confirmed is 180 seconds or more.
Evaluation “Good”: The time until swelling is confirmed is 120 seconds or more and less than 180 seconds.
Evaluation “Possible”: The time until swelling is confirmed is 60 seconds or more and less than 120 seconds.
Evaluation “Not possible”: The time until swelling is confirmed is less than 60 seconds.

### Examples 2 to 22 and Comparative Examples 1 to 3

A resin composition for an antenna-equipped semiconductor package was prepared in the same manner as in Example 1, except that the formulation of the resin composition for the antenna-equipped semiconductor package was changed to Tables 1 to 3.

Next, a coating solution containing each resin composition for an antenna-equipped semiconductor package of Examples 2 to 22 and Comparative Examples 1 to 3 was applied to one side of a support and dried at 120° C. to obtain an adhesive film with a support, respectively, and a test specimen (a cured adhesive film) was prepared in the same manner as in Example 1. In the same manner as in Example 1, the dielectric constant (s), the dielectric loss tangent (tan δ), the peel strength, and the solder heat resistance test were evaluated for each of the prepared test specimens. The results are shown in Tables 1 to 3.

In Example 2 to 22 and Comparative Examples 1 to 3, raw materials used for preparing the resin composition for the antenna-equipped semiconductor package are as follows.
(A1): Styrene-based elastomer having a double bond (non-hydrogenated, SBS), manufactured by JSR Corporation, trade name “TR2003”.
(A2): Styrene-based elastomer having a double bond (partially hydrogenated, SBBS), manufactured by Asahi Kasei Chemicals Corporation, trade name “P1083”.
(A3): Styrene-based elastomer having a double bond (partially hydrogenated, SBBS), manufactured by Asahi Kasei Chemicals Corporation, trade name “P1500”.
(A4): Styrene-based elastomer having a double bond (partially hydrogenated, SBBS), manufactured by Asahi Kasei Chemicals Corporation, trade name “P5051”.
(A5): Styrene-based elastomer having a double bond (partially hydrogenated, amine-modified SBBS), manufactured by Asahi Kasei Chemicals Corporation, trade name “MP10”.
(A6): Styrene-based elastomer having no double bond (hydrogenated), manufactured by Asahi Kasei Chemicals Corporation, trade name “H1052”.
(B1): A compound generating a radical (degradable), manufactured by NOF Corporation, trade name “PERCUMYL D”.
(B2): A compound generating a radical (non-degradable), manufactured by Mitsubishi Gas Chemical Company Inc., trade name “OPE-2St 1200”.
(B3): A compound generating a radical (non-degradable), manufactured by Mitsubishi Gas Chemical Company Inc., trade name “OPE-2St 2200”.
(C1): Curing agent, imidazole manufactured by ADEKA Corporation, trade name “EH2021”.
(C2): Organic filler, PTFE manufactured by Daikin Industries, Ltd., “Lublon L-5F”.
(C3): Inorganic filler, silica manufactured by Denka Company Limited, trade name “FB3 SDX”.
(E): Epoxy resin, bisphenol A type epoxy resin manufactured by Mitsubishi Chemical Corporation, trade name “828EL”.

TABLE 1

| | | | | Example | Example | Example | Example |
|---|---|---|---|---|---|---|---|
| | | | | 1 | 2 | 3 | 4 |
| Raw | Component(A) | (A1) Styrene-based elastomer | Non- | — | — | — | — |
| material | | (with doublebond) | hydrogenated | | | | |
| (parts by | | (A2) Styrene-based elastomer | Partially | — | — | — | — |
| mass) | | (with double bond) | hydrogenated | | | | |
| | | (A3) Styrene-based elastomer | Partially | 99.75 | 85.00 | 84.75 | 79.84 |
| | | (with double bond) | hydrogenated | | | | |
| | | (A4) Styrene-based elastomer | Partially | — | — | — | — |
| | | (with double bond) | hydrogenated | | | | |
| | | (A5) Amine-modified styrene-based | Partially | — | — | — | — |
| | | elastomer (with double bond) | hydrogenated | | | | |
| | | (A6) Styrene-based elastomer | Hydrogenated | — | — | — | — |
| | | (without double bond) | | | | | |
| | Component(B) | (B1) Compound generating | | 0.25 | — | 0.30 | 0.20 |
| | | radical (degradable) | | | | | |
| | | (B2) Compound generating | | — | 15.00 | 14.96 | 19.96 |
| | | radical (non-degradable) | | | | | |
| | | (B3) Compound generating | | — | — | — | — |
| | | radical (non-degradable) | | | | | |
| | Other | (E) Bisphenol A type epoxy resin | | — | — | — | — |
| | | (C1) Curing agent | Imidazole | — | — | — | — |
| | | (C2) Organic filler | PTFE | — | — | — | — |
| | | (C3) Inorganic filler | Silica | — | — | — | |
| | Total (parts by mass) | | | 100.00 | 100.00 | 100.01 | 100.00 |
| Evaluation | Dielectric constant (ε) | | | 2.33 | 2.33 | 2.39 | 2.35 |
| | Dielectric loss tangent (tan δ) | | | 0.0014 | 0.0014 | 0.0013 | 0.0014 |
| | Peel strength (N/cm) | | | 12 | 6 | 17 | 1 |
| | Solder heat resistance test (seconds) | | | 240 | 240 | 240 | 240 |
| | | | | Example | Example | Example | Example |
| | | | | 5 | 6 | 7 | 8 |
| Raw | Component(A) | (A1) Styrene-based elastomer | Non- | — | — | — | — |
| material | | (with doublebond) | hydrogenated | | | | |
| (parts by | | (A2) Styrene-based elastomer | Partially | — | — | — | — |
| mass) | | (with double bond) | hydrogenated | | | | |
| | | (A3) Styrene-based elastomer | Partially | 29.90 | 41.90 | 55.89 | 55.89 |
| | | (with double bond) | hydrogenated | | | | |
| | | (A4) Styrene-based elastomer | Partially | — | — | — | — |
| | | (with double bond) | hydrogenated | | | | |
| | | (A5) Amine-modified styrene-based | Partially | — | — | — | — |
| | | elastomer (with double bond) | hydrogenated | | | | |
| | | (A6) Styrene-based elastomer | Hydrogenated | — | — | — | — |
| | | (without double bond) | | | | | |
| | Component(B) | (B1) Compound generating | | 0.30 | 0.20 | 0.14 | 0.14 |
| | | radical (degradable) | | | | | |
| | | (B2) Compound generating | | 69.80 | 27.90 | 13.97 | — |
| | | radical (non-degradable) | | | | | |
| | | (B3) Compound generating | | — | — | — | 13.97 |
| | | radical (non-degradable) | | | | | |

| | | | | | |
|---|---|---|---|---|---|
| Other | (E) Bisphenol A type epoxy resin | — | — | — | — |

| | | | | | |
|---|---|---|---|---|---|
| (C1) Curing agent | Imidazole | — | — | — | — |
| (C2) Organic filler | PTFE | — | 30.00 | 30.00 | 30.00 |
| (C3) Inorganic filler | Silica | — | — | — | — |

| | | | | | |
|---|---|---|---|---|---|
| | Total (parts by mass) | 100.00 | 100.00 | 100.00 | 100.00 |
| Evaluation | Dielectric constant (ε) | 2.42 | 2.38 | 2.33 | 2.37 |
| | Dielectric loss tangent (tan δ) | 0.0019 | 0.0014 | 0.0013 | 0.0012 |
| | Peel strength (N/cm) | 6 | 8 | 10 | 10 |
| | Solder heat resistance test (seconds) | 125 | 240 | 240 | 240 |

TABLE 2

| | | | | Example | Example | Example | Example |
|---|---|---|---|---|---|---|---|
| | | | | 9 | 10 | 11 | 12 |
| Raw | Component (A) | (A1) Styrene-based elastomer | Non- | — | — | — | — |
| material | | (with double bond) | hydrogenated | | | | |
| (parts by | | (A2) Styrene-based elastomer | Partially | 55.89 | — | — | — |
| mass) | | (with double bond) | hydrogenated | | | | |
| | | (A3) Styrene-based elastomer | Partially | — | — | — | 62.81 |
| | | (with double bond) | hydrogenated | | | | |
| | | (A4) Styrene-based elastomer | Partially | — | 55.89 | 41.90 | — |
| | | (with double bond) | hydrogenated | | | | |
| | | (A5) Amine-modified styrene-based | Partially | — | — | — | — |
| | | elastomer (with double bond) | hydrogenated | | | | |
| | | (A6) Styrene-based elastomer | Hydrogenated | — | — | — | — |
| | | (without double bond) | | | | | |
| | Component (B) | (B1) Compound generating | | 0.14 | 0.14 | 0.20 | 0.21 |
| | | radical (degradable) | | | | | |
| | | (B2) Compound generating | | 13.97 | 13.97 | 27.90 | 6.98 |
| | | radical (non-degradable) | | | | | |
| | | (B3) Compound generating | | — | — | — | — |
| | | radical (non-degradable) | | | | | |
| | Other | (E) Bisphenol A type epoxy resin | | — | — | — | — |
| | | (C1) Curing agent | Imidazole | — | — | — | — |
| | | (C2) Organic filler | PTFE | 30.00 | 30.00 | 30.00 | 30.00 |
| | | (C3) Inorganic filler | Silica | — | — | — | — |
| | Total (parts by mass) | | | 100.00 | 100.00 | 100.00 | 100.00 |
| Evaluation | Dielectric constant (ε) | | | 2.31 | 2.39 | 2.4 | 2.3 |
| | Dielectric loss tangent (tan δ) | | | 0.0009 | 0.0013 | 0.0015 | 0.0011 |
| | Peel strength (N/cm) | | | 10 | 25 | 23 | 28 |
| | Solder heat resistance test (seconds) | | | 240 | 240 | 240 | 240 |
| | | | | Example | Example | Example | Example |
| | | | | 13 | 14 | 15 | 16 |
| Raw | Component (A) | (A1) Styrene-based elastomer | Non- | — | — | — | — |
| material | | (with double bond) | hydrogenated | | | | |
| (parts by | | (A2) Styrene-based elastomer | Partially | — | — | — | — |
| mass) | | (with double bond) | hydrogenated | | | | |
| | | (A3) Styrene-based elastomer | Partially | 55.09 | 47.90 | 53.80 | 26.89 |
| | | (with double bond) | hydrogenated | | | | |
| | | (A4) Styrene-based elastomer | Partially | — | — | — | — |
| | | (with double bond) | hydrogenated | | | | |
| | | (A5) Amine-modified styrene-based | Partially | — | — | — | — |
| | | elastomer (with double bond) | hydrogenated | | | | |
| | | (A6) Styrene-based elastomer | Hydrogenated | — | — | — | — |
| | | (without double bond) | | | | | |
| | Component (B) | (B1) Compound generating | | 0.19 | 0.10 | 0.20 | 0.18 |
| | | radical (degradable) | | | | | |
| | | (B2) Compound generating | | 9.72 | 12.00 | 6.00 | 17.93 |
| | | radical (non-degradable) | | | | | |
| | | (B3) Compound generating | | — | — | — | — |
| | | radical (non-degradable) | | | | | |

| | | | | | |
|---|---|---|---|---|---|
| Other | (E) Bisphenol A type epoxy resin | — | — | — | — |

| | | | | | |
|---|---|---|---|---|---|
| (C1) Curing agent | Imidazole | — | — | — | — |
| (C2) Organic filler | PTFE | 35.00 | 40.00 | 40.00 | 55.00 |
| (C3) Inorganic filler | Silica | — | — | — | — |

| | | | | | |
|---|---|---|---|---|---|
| | Total (parts by mass) | 100.00 | 100.00 | 100.00 | 100.00 |
| Evaluation | Dielectric constant (ε) | 2.33 | 2.3 | 2.29 | 2.31 |
| | Dielectric loss tangent (tan δ) | 0.0011 | 0.0010 | 0.0007 | 0.0013 |
| | Peel strength (N/cm) | 26 | 6 | 21 | 2 |
| | Solder heat resistance test (seconds) | 240 | 240 | 240 | 240 |

TABLE 3

| | | | | Example | Example | Example | Example | Example |
|---|---|---|---|---|---|---|---|---|
| | | | | 17 | 18 | 19 | 20 | 21 |
| Raw | Component (A) | (A1) Styrene-based elastomer | Non- | — | — | — | — | 41.9 |
| mateial | | (with double bond) | hydrogenated | | | | | |
| (parts by | | (A2) Styrene-based elastomer | Partially | — | — | — | — | — |
| mass) | | (with double bond) | hydrogenated | | | | | |
| | | (A3) Styrene-based elastomer | Partially | 25.82 | 35.86 | 40.34 | 59.30 | — |
| | | (with double bond) | hydrogenated | | | | | |
| | | (A4) Styrene-based elastomer | Partially | — | — | — | — | — |
| | | (with double bond) | hydrogenated | | | | | |
| | | (A5) Amine-modified styrene-based | Partially | — | — | — | — | — |
| | | elastomer (with double bond) | hydrogenated | | | | | |
| | | (A6) Styrene-based elastomer | Hydrogenated | | — | — | — | — |
| | | (without double bond) | | | | | | |
| | Component (B) | (B1) Compound generating | | 0.17 | 0.18 | 0.18 | 0.20 | 0.20 |
| | | radical (degradable) | | | | | | |
| | | (B2) Compound generating | | 17.21 | 8.96 | 4.48 | 10.50 | 27.90 |
| | | radical (non-degradable) | | | | | | |
| | | (B3) Compound generating | | — | — | — | — | — |
| | | radical (non-degradable) | | | | | | |

| | | | | | | |
|---|---|---|---|---|---|---|
| Other | (E) Bisphenol A type epoxy resin | 1.72 | — | — | — | — |

| | | | | | | |
|---|---|---|---|---|---|---|
| (C1) Curing agent | Imidazole | 0.07 | — | — | — | — |
| (C2) Organic filler | PTFE | 55.00 | 55.00 | 55.00 | — | 30.00 |
| (C3) Inorganic filler | Silica | — | — | — | 30.00 | — |

| | | | | | | |
|---|---|---|---|---|---|---|
| | Total (parts by mass) | 99.99 | 100.00 | 100.00 | 100.00 | 100.00 |
| Evaluation | Dielectric constant (ε) | 2.43 | 2.29 | 2.3 | 2.58 | 2.45 |
| | Dielectric loss tangent (tan δ) | 0.0019 | 0.0010 | 0.0010 | 0.0014 | 0.0020 |
| | Peel strength (N/cm) | 5 | 2 | 2 | 22 | 10 |
| | Solder heat resistance test (seconds) | 240 | 240 | 240 | 240 | 240 |

| | | | | Example | Comparative | Comparative | Comparative |
|---|---|---|---|---|---|---|---|
| | | | | 22 | Example 1 | Example 2 | Example 3 |
| Raw | Component (A) | (A1) Styrene-based elastomer | Non- | — | — | — | — |
| mateial | | (with double bond) | hydrogenated | | | | |
| (parts by | | (A2) Styrene-based elastomer | Partially | — | — | — | — |
| mass) | | (with double bond) | hydrogenated | | | | |
| | | (A3) Styrene-based elastomer | Partially | — | 100.00 | 70.00 | — |
| | | (with double bond) | hydrogenated | | | | |
| | | (A4) Styrene-based elastomer | Partially | — | — | — | — |
| | | (with double bond) | hydrogenated | | | | |
| | | (A5) Amine-modified styrene-based | Partially | 55.09 | — | — | — |
| | | elastomer (with double bond) | hydrogenated | | | | |
| | | (A6) Styrene-based elastomer | Hydrogenated | — | — | — | 26.90 |
| | | (without double bond) | | | | | |
| | Component (B) | (B1) Compound generating | | 0.19 | — | — | 0.20 |
| | | radical (degradable) | | | | | |
| | | (B2) Compound generating | | 9.72 | — | — | 17.90 |
| | | radical (non-degradable) | | | | | |
| | | (B3) Compound generating | | — | — | — | — |
| | | radical (non-degradable) | | | | | |

| | | | | | |
|---|---|---|---|---|---|
| Other | (E) Bisphenol A type epoxy resin | — | — | — | — |

| | | | | | |
|---|---|---|---|---|---|
| (C1) Curing agent | Imidazole | — | — | — | — |
| (C2) Organic filler | PTFE | 35.00 | — | 30.00 | 55.00 |
| (C3) Inorganic filler | Silica | — | — | — | — |

| | | | | | |
|---|---|---|---|---|---|
| | Total (parts by mass) | 100.00 | 100.00 | 100.00 | 100.00 |
| Evaluation | Dielectric constant (ε) | 2.31 | 2.33 | 2.32 | 2.23 |
| | Dielectric loss tangent (tan δ) | 0.0009 | 0.0011 | 0.0010 | 0.0009 |
| | Peel strength (N/cm) | 30 | 1.3 | 4.8 | 9.1 |
| | Solder heat resistance test (seconds) | 240 | 10 | 20 | 10 |

As shown in Tables 1 to 3, a cured product of a resin composition containing a styrene-based elastomer having a double bond as the component (A) and a compound generating a radical as the component (B) exhibited good values with respect to dielectric constant (c) and dielectric loss tangent (tan δ). In addition, such a cured product also showed good results in peel strength and solder heat resistance test.

On the other hand, since the resin composition of Comparative Example 1 did not contain a compound generating a radical as the component (B), the evaluation result of the peel strength and the solder heat resistance test were very poor. The resin composition of Comparative Example 2 contains a certain amount of an organic filler ((C2) PTFE), but does not contain a compound generating a radical as the component (B), so that the evaluation result of the solder heat resistance test was very poor. The resin composition of Comparative Example 3 was a resin composition using a styrene-based elastomer having no double bond as the component (A), and was excellent in peel strength, but the evaluation result of the solder heat resistance test was very poor.

### INDUSTRIAL APPLICABILITY

The antenna-equipped semiconductor package of the present invention can be used as a high-frequency substrate on which an RF chip that performs transmission/reception communication of 5G millimeter waves is mounted. The resin composition for the antenna-equipped semiconductor package of the present invention can be used for an insulating layer of the antenna-equipped semiconductor package of the present invention.

### EXPLANATION OF REFERENCE NUMERALS

1 Insulating layer
1A First insulating layer
1B Second insulating layer
1C Third insulating layer
1D Fourth insulating layer
1E Fifth insulating layer
2 Core substrate
4 Wiring layer
5 Antenna unit (patch antenna)
7 Electrical connection metal
8 RF chip
9 Connecting pad
10 Semiconductor device unit
21 Insulating layer
22 Core substrate
24 Wiring layer
25 Antenna unit (patch antenna)
26 Antenna unit (dipole antenna)
27 Electrical connection metal
28 RF chip
30 Semiconductor device unit
100, 200 Antenna-equipped semiconductor package

1. An antenna-equipped semiconductor package in which an antenna unit is integrally formed in a semiconductor device unit, wherein
at least one of an insulating layer for connecting the semiconductor device unit and the antenna unit, and an insulating layer inside the antenna unit, is a cured product of a resin composition containing (A) a styrene-based elastomer having a double bond and (B) a compound generating a radical.

2. The antenna-equipped semiconductor package according to claim 1, wherein a total mass of an epoxy resin and a curing agent in the cured product is 5 parts by mass or less with respect to 100 parts by mass of a total of the styrene-based elastomer (A) having a double bond and the compound (B) generating a radical.

3. The antenna-equipped semiconductor package according to claim 1, wherein the styrene-based elastomer (A) having a double bond comprises a styrene/butadiene/butylene/styrene block copolymer.

4. The antenna-equipped semiconductor package according to claim 1, wherein the cured product comprises PTFE fillers.

5. A resin composition for an antenna-equipped semiconductor package, comprising: (A) a styrene-based elastomer having a double bond; and (B) a compound generating a radical.

6. The resin composition for an antenna-equipped semiconductor package according to claim 5, wherein a total mass of an epoxy resin and a curing agent in the resin composition is 5 parts by mass or less with respect to 100 parts by mass of a total of the styrene-based elastomer (A) having a double bond and the compound (B) generating a radical.

7. The resin composition for an antenna-equipped semiconductor package according to claim 5, wherein the styrene-based elastomer (A) having a double bond comprises a styrene/butadiene/butylene/styrene block copolymer.

8. The resin composition for an antenna-equipped semiconductor package according to claim 5, comprising PTFE fillers.

9. A film for an antenna-equipped semiconductor package comprising the resin composition according to claim 5.
